(19) United States
(12) Patent Application Publication
(10) Pub. No.: US 2020/0239998 A1
(43) Pub. Date: Jul. 30, 2020

(54) VAPOR DEPOSITION STRUCTURE OF DISPLAY PANEL

(71) Applicant: Wuhan China Star Optoelectronics Technology Co., Ltd., Wuhan, Hubei (CN)

(72) Inventor: Kaixiang ZHAO, Wuhan, Hubei (CN)

(21) Appl. No.: 16/472,888

(22) PCT Filed: Jan. 23, 2019
(86) PCT No.: PCT/CN2019/072868

§ 371 Date: Jun. 23, 2019

(30) Foreign Application Priority Data
Dec. 18, 2018 (CN) 201811550408.0

(51) Int. Cl. C23C 14/04; C23C 14/50; C23C 14/24

(52) U.S. Cl. CPC C23C 14/042; C23C 14/24; C23C 14/50

(57) ABSTRACT

A vapor deposition structure of a display panel includes a display panel, a plurality of magnets distributed on one side of the display panel, a mask disposed on another side of the display panel, a plurality of support columns supported between the mask and the display panel, and a vapor deposition source having a vapor deposition side facing the mask. Each of the support columns corresponds to one of the magnets. In the vapor deposition structure of the display panel, by adding the support columns in corresponding regions of the mask and the magnets, a deformation issue caused by an uneven distribution of an adsorption force generated by the magnets is effectively prevented. This ensures a uniform thickness of each light emitting layer structure after vapor deposition, which reduces a defect rate displayed on the display panel.

### FIELD OF INVENTION

The present disclosure relates to the field of vapor deposition equipments of display panels, and more particularly to a vapor deposition structure of a display panel.

### BACKGROUND OF INVENTION

In processes of display panels, a vapor deposition process is required to form a corresponding functional film layer. The vapor deposition process generally uses electric current heating, electron beam bombardment heating, and laser heating in a vacuum to evaporate vaporized material into atoms or molecules. The atoms or molecules then move in a straight line with a large free path, collide with a surface of a substrate, and condense to form a film. In the case of vapor deposition, it is necessary to use a mask to mask a non-film formation area, such that each functional film layer can be formed at a specified position.

In current vapor deposition devices, when the display panel is vapor deposited, magnets in the vapor deposition device generate an adsorption force to a mask to adsorb the mask. However, the magnets in the current vapor deposition device can only be made into a strip shape. When the magnets are energized, a magnetic field near the magnets is strong, and the magnetic field away from the magnets is weak, such an uneven distribution of an adsorption force of the magnets is caused when the mask in the vapor deposition device is adsorbed by the magnets. The mask is easily deformed due to the uneven adsorption force, and finally affects uniformity of a thickness of the functional film layer after vapor deposition, resulting in display failure of the display panel.

### SUMMARY OF INVENTION

In order to solve the above technical problems, the present disclosure provides a vapor deposition structure of a display panel, which is provided by adding a plurality of support columns between a mask and a display panel to prevent deformation of the mask caused by an uneven distribution of an adsorption force generated by magnets.

A technical solution to solve the above issues is that the present disclosure provides a vapor deposition structure of a display panel includes a display panel, a plurality of magnets distributed on one side of the display panel, a mask disposed on another side of the display panel, a plurality of support columns supported between the mask and the display panel, and a vapor deposition source having a vapor deposition side facing the mask. Each of the support columns corresponds to one of the magnets.

In an embodiment of the present disclosure, the vapor deposition structure of the display panel according further includes a bottom plate, the magnets are disposed on one side of the bottom plate, and the display panel is disposed on another side of the bottom plate, the display panel includes a glass substrate disposed on the bottom plate, a thin film transistor structural layer disposed on the glass substrate, a pixel defining layer disposed on the thin film transistor structure layer and provided with a plurality of openings, and a spacer pillar disposed on the pixel defining layer, the mask is disposed on the spacer pillar, and the support columns are disposed in a same layer as the spacer pillar.

In an embodiment of the present disclosure, the mask has a plurality of through-hole regions and a plurality of non-perforated regions, and each of the through-hole regions corresponds to one of the openings.

In an embodiment of the present disclosure, the through-hole regions are arranged in an array to form a plurality of rows and a plurality of columns of the through-hole regions, the support columns are arranged in an array and positioned in the non-perforated regions to form a plurality of rows and a plurality of columns of the support columns, the rows of the support columns are parallel to the rows of the through-hole regions, and the columns of the support columns are parallel to the columns of the through-hole regions.

In an embodiment of the present disclosure, the support columns and the through-hole regions are staggered in a direction in which the rows of the support columns are positioned or in a direction in which the columns of the support columns are positioned.

In an embodiment of the present disclosure, the magnets are elongated, and each row or each column of the support columns corresponds to one magnet.

In an embodiment of the present disclosure, the vapor deposition structure of the display panel further includes a light emitting layer structure disposed in each of the openings, the light emitting layer structure is one of a red light emitting layer structure, a green light emitting layer structure, and a blue light emitting layer structure.

In an embodiment of the present disclosure, each of the through-hole regions corresponds to the red light emitting layer structure, and the non-perforated regions correspond to the green light emitting layer structure and the blue light emitting layer structure, or each of the through-hole regions corresponds to the blue light emitting layer structure, and the non-perforated regions correspond to the green light emitting layer structure and the red light emitting layer structure, or each of the through-hole regions corresponds to the green light emitting layer structure, and the non-perforated regions correspond to the red light emitting layer structure and the blue light emitting layer structure.

In an embodiment of the present disclosure, wherein a shape and size of each of the through-hole regions are matched to a shape and size of a corresponding opening.

In an embodiment of the present disclosure, each of the support columns is a prismatic columnar structure.

Beneficial effects of the embodiment of the present disclosure: in the vapor deposition structure of the display panel of the embodiment of the present disclosure, by adding the support columns in corresponding regions of the mask and the magnets, a deformation issue caused by an uneven distribution of an adsorption force generated by the magnets is effectively prevented. This ensures a uniform thickness of each light emitting layer structure after vapor deposition, which reduces a defect rate displayed on the display panel.

### DESCRIPTION OF DRAWINGS

In order to more clearly illustrate the technical solutions in the embodiments of the present disclosure, the drawings used in the description of the embodiments will be briefly described below. It is obvious that the drawings in the following description are only some embodiments of the present disclosure. Other drawings can also be obtained from those skilled in the art based on these drawings without paying any creative effort.

The present disclosure is further explained below in conjunction with the drawings and embodiments.

FIG. 1 is a structural view illustrating a corresponding relationship between a mask and a plurality of magnets according to an embodiment of the present disclosure, mainly illustrating a corresponding relationship between a plurality of support columns and the magnets on the mask.

FIG. 2 is a schematic view illustrating a vapor deposition structure of a display panel when a red light emitting structure is vapor deposited according to an embodiment of the present disclosure.

FIG. 3 is a schematic view illustrating a vapor deposition structure of a display panel when a blue light emitting structure is vapor deposited according to an embodiment of the present disclosure.

FIG. 4 is a schematic view illustrating a vapor deposition structure of a display panel when a green light emitting structure is vapor deposited according to an embodiment of the present disclosure.

### DETAILED DESCRIPTION OF PREFERRED EMBODIMENTS

The embodiments of the present disclosure are described in detail below, and the examples of the embodiments are illustrated in the drawings, wherein the same or similar reference numerals indicate the same or similar elements or elements having the same or similar functions. The embodiments described below with reference to the drawings are intended to be illustrative of the present disclosure and are not to be construed as limiting.

The following description of the embodiments is provided to illustrate the specific embodiments of the present disclosure. The directional terms mentioned in the present disclosure, such as “upper”, “lower”, “front”, “back”, “left”, “right”, “top”, “bottom”, etc., are only referred to as an orientation of the drawings. Therefore, the directional terms are used to illustrate and understand the present disclosure and are not intended to limit the present disclosure.

As illustrated in FIG. 2 to FIG. 4, in an embodiment of the present disclosure, a vapor deposition structure 1 of a display panel includes a bottom plate 11, a display panel 12, a plurality of magnets 13, a mask 14, a plurality of support columns 15, and a vapor deposition source 16.

The display panel 12 is disposed on one side of the bottom plate 11, and the magnets 13 are distributed on another side of the bottom plate 11. In the embodiment, the magnets 13 are elongated, and the elongated magnets 13 are parallel to each other.

The display panel 12 includes a glass substrate 121, a thin film transistor structure layer 122, a pixel defining layer 123, and a spacer pillar 124. The thin film transistor structure layer 122 is disposed on the glass substrate 121, and the thin film transistor structure layer 122 has a plurality of thin film transistors (not shown). The pixel defining layer 123 is disposed on the thin film transistor structure layer 122. The pixel defining layer 123 is provided with a plurality of openings 126 corresponding to the thin film transistors, and the spacer pillar 124 is disposed on the pixel defining layer 123.

The mask 14 is disposed on another side of the display panel 12, that is, a side of the display panel 12 having the spacer pillar 124.

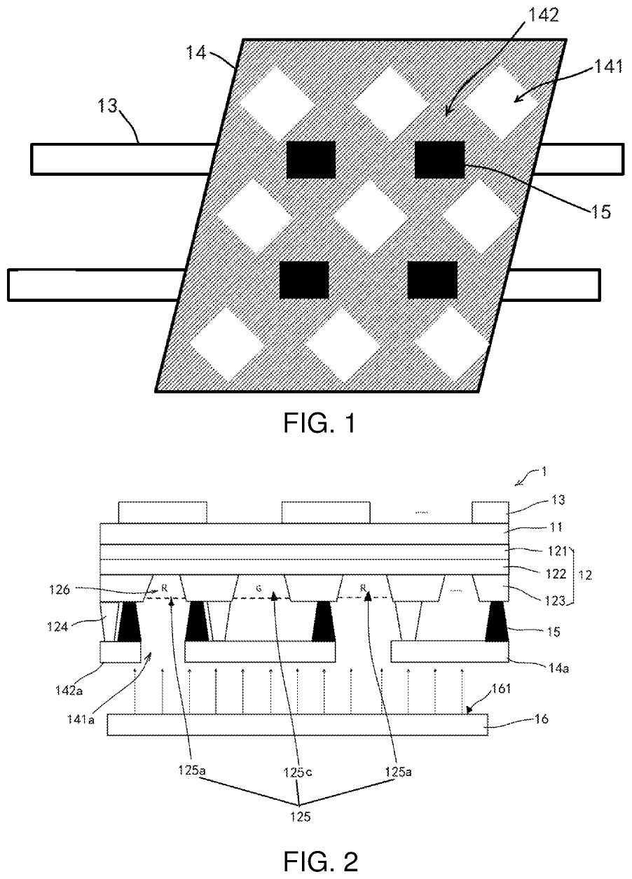

Referring to FIG. 1, in details, the mask 14 has a plurality of through-hole regions 141 and a plurality of non-perforated regions 142. The through-hole regions 141 are arranged in an array to form a plurality of rows and a plurality of columns of the through-hole regions 141, the support columns 15 are positioned in the non-perforated regions 142 and also arranged in an array to form a plurality of rows and a plurality of columns of the support columns 15, the rows of the support columns 15 are parallel to the rows of the through-hole regions 141, and the columns of the support columns 15 are parallel to the columns of the through-hole regions 141. The support columns 15 and the through-hole regions 141 are staggered in a direction in which the rows of the support columns 15 are positioned or in a direction in which the columns of the support columns 15 are positioned.

Referring to FIG. 2 to FIG. 4, the support columns 15 are supported between the mask 14 and the display panel 12, and the support columns 15 are disposed in a same layer as the spacer pillar 124, that is, the support columns 15 are supported between the mask 14 and the pixel defining layer 123. Each of the support column 15 is a prismatic columnar structure, and may be other structures, such as a cylindrical structure. In order to prevent the support columns 15 from interfering with the spacer pillar 124, in the embodiment, each of the support columns 15 is designed as a prismatic columnar structure having a plurality of first sides, and the spacer pillar 124 has a plurality of second sides, the first sides are parallel to the second sides when the support columns 15 are adjacent to the spacer pillar 124, this facilitates space saving and avoids interference of the support columns 15 with the spacer pillar 124.

Because the magnets 13 are elongated, in the embodiment, each row or each column of the support columns 15 corresponds to one magnet 13. If a width of the magnet 13 is large, two rows or two columns of the support columns 15 correspond to one magnet 13.

Because a light emitting layer structure 125 needs to be formed in the openings 126 during vapor deposition, each of the through-hole regions 141 in the embodiment corresponds to one of the openings 126. The light emitting layer structure 125 is one of a red light emitting layer structure 125a, a green light emitting layer structure 125c, and a blue light emitting layer structure 125b. In one display panel 12, there are a plurality of red light emitting layer structures 125a, a plurality of green light emitting layer structures 125c, and a plurality of blue light emitting layer structures 125b.

In the embodiment, each of the through-hole regions 141 corresponds to each of the red light emitting layer structures 125a, and the non-perforated regions 142 correspond to the green light emitting layer structures 125c and the blue light emitting layer structures 125b. During an actual vapor deposition process, the red light emitting layer structures 125a are formed in the openings 126 corresponding to the through-hole regions 141, and the openings 126 corresponding to the non-perforated regions 142 are blocked.

It is understood that, each of the through-hole regions 141 corresponds to each of the blue light emitting layer structures 125b, and the non-perforated regions 142 correspond to the green light emitting layer structures 125c and the red light emitting layer structures 125a. During an actual vapor deposition process, the blue light emitting layer structures 125b are formed in the openings 126 corresponding to the through-hole regions 141, and the openings 126 corresponding to the non-perforated regions 142 are blocked.

In addition, each of the through-hole regions 141 corresponds to each of the green light emitting layer structures 125c, and the non-perforated regions 142 correspond to the red light emitting layer structures 125a and the blue light emitting layer structures 125b. During an actual vapor deposition process, the green light emitting layer structures 125c are formed in the openings 126 corresponding to the through-hole regions 141, and the openings 126 corresponding to the non-perforated regions 142 are blocked.

In the embodiment, wherein a shape and size of each of the through-hole regions 141 are matched to a shape and size of a corresponding opening 126, such that the shape and size of the light emitting layer structure 125 meet design requirements.

The vapor deposition source 16 has a vapor deposition side 161 facing the mask 14, and the vapor deposition source 16 provides vapor deposition material for forming the light emitting layer structure 125. The vapor deposition material forms the light emitting layer structure 125 from the vapor deposition side 161 through the through-hole regions 141 in the corresponding opening 126.

In order to explain the present disclosure more clearly, the vapor deposition structure 1 of the display panel of the present disclosure will be further described below in conjunction with a vapor deposition method of a light emitting layer structure of a display panel.

The vapor deposition method of the light emitting layer structure of the display panel includes following steps.

As illustrated in FIG. 2, the display panel 12 is placed on one side of the bottom plate 11, the magnets 13 arranged in parallel with each other are disposed on another side of the bottom plate 11. The display panel 12 is provided with the glass substrate 121, the thin film transistor structure layer 122, the pixel defining layer 123, and the spacer pillar 124 in order on the bottom plate 11. The pixel defining layer 123 is provided with the openings 126 corresponding to the thin film transistors, and the spacer pillar 124 is disposed on the pixel defining layer 123.

A first mask 14a is provided. The first mask 14a has a plurality of first through-hole regions 141a and a plurality of first non-perforated regions 142a. The first through-hole regions 141a are arranged in an array to form a plurality of rows and a plurality of columns of the first through-hole regions 141a. The support columns 15 are disposed in the first non-perforated regions 142a, and the support columns 15 are also arranged in an array to form rows and columns of the support columns 15. The rows of the support columns 15 are parallel to the rows of the first through-hole regions 141a, and the columns of the support columns 15 are parallel to the columns of the first through-hole regions 141a. The support columns 15 are staggered with the first through-hole regions 141a in a direction in which the rows of the support columns 15 are positioned or in a direction in which the columns of the support columns 15 are positioned. Each row or each column of the support columns 15 corresponds to one magnet 13.

The first mask 14a with the support columns 15 is disposed on the display panel 12, and the support columns 15 are supported between the mask 14 and the display panel 12. The support columns 15 are disposed in the same layer as the spacer pillar 124, that is, the support columns 15 are supported between the first mask 14a and the pixel defining layer 123.

The vapor deposition source 16 is provided to vaporize the display panel 12, the vapor deposition source 16 has a vapor deposition side 161 facing the first mask 14a, and the vapor deposition source 16 provides vapor deposition material for forming the red light emitting layer structures 125a. The red light emitting layer structures 125a are formed in the openings 126 corresponding to the through-hole regions 141, and the openings 126 corresponding to the non-perforated regions 142 are blocked.

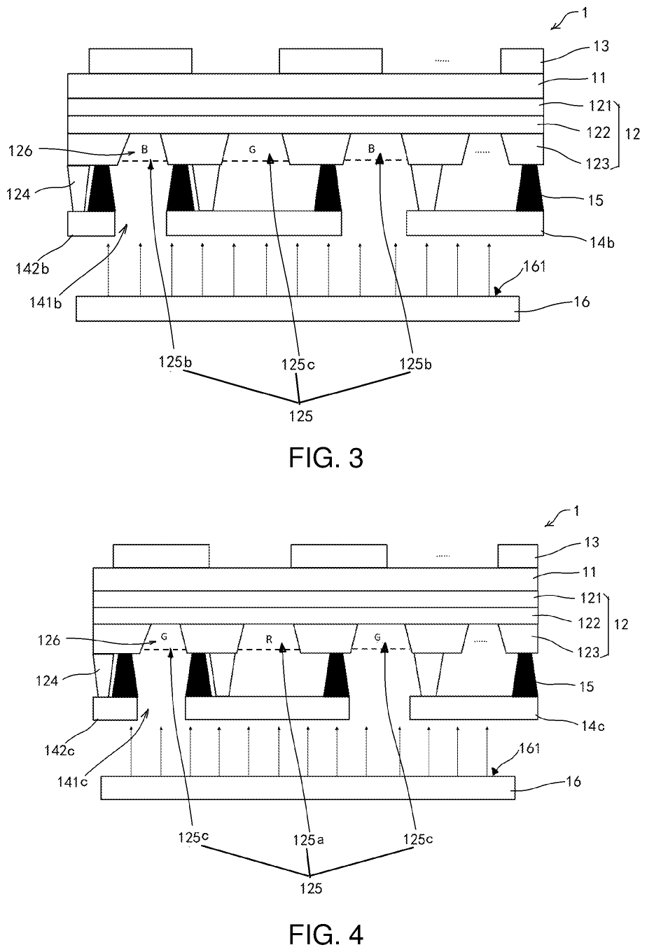

As illustrated in FIG. 3, after the preparation of the red light emitting layer structures 125a is completed, the second mask 14b is replaced. The second mask 14b has a plurality of second through-hole regions 141b and a plurality of second non-perforated regions 142b. The second through-hole regions 141b are arranged in an array to form a plurality of rows and a plurality of columns of the second through-hole regions 141b. The support columns 15 are disposed in the second non-perforated regions 142b, and the support columns 15 are also arranged in an array to form rows and columns of the support columns 15. The rows of the support columns 15 are parallel to the rows of the second through-hole regions 141b, and the columns of the support columns 15 are parallel to the columns of the second through-hole regions 141b. The support columns 15 are staggered with the second through-hole regions 141b in a direction in which the rows of the support columns 15 are positioned or in a direction in which the columns of the support columns 15 are positioned. Each row or each column of the support columns 15 corresponds to one magnet 13.

The second mask 14b with the support columns 15 is disposed on the display panel 12, and the support columns 15 are supported between the second mask 14b and the display panel 12. The support columns 15 are disposed in the same layer as the spacer pillar 124, that is, the support columns 15 are supported between the mask 14 and the pixel defining layer 123.

The vapor deposition source 16 is provided to vaporize the display panel 12, the vapor deposition source 16 has a vapor deposition side 161 facing the second mask 14b, and the vapor deposition source 16 provides vapor deposition material for forming the blue light emitting layer structures 125b. The blue light emitting layer structures 125b are formed in the openings 126 corresponding to the through-hole regions 141, and the openings 126 corresponding to the non-perforated regions 142 are blocked.

As illustrated in FIG. 4, after the preparation of the blue light emitting layer structures 125b is completed, the third mask 14c is replaced. The third mask 14c has a plurality of third through-hole regions 141c and a plurality of third non-perforated regions 142c. The third through-hole regions 141c are arranged in an array to form a plurality of rows and a plurality of columns of the third through-hole regions 141c. The support columns 15 are disposed in the third non-perforated regions 142c, and the support columns 15 are also arranged in an array to form rows and columns of the support columns 15. The rows of the support columns 15 are parallel to the rows of the third through-hole regions 141c, and the columns of the support columns 15 are parallel to the columns of the third through-hole regions 141c. The support columns 15 are staggered with the third through-hole regions 141c in a direction in which the rows of the support columns 15 are positioned or in a direction in which the columns of the support columns 15 are positioned. Each row or each column of the support columns 15 corresponds to one magnet 13.

The third mask 14c with the support columns 15 is disposed on the display panel 12, and the support columns 15 are supported between the third mask 14c and the display panel 12. The support columns 15 are disposed in the same layer as the spacer pillar 124, that is, the support columns 15 are supported between the mask 14 and the pixel defining layer 123.

The vapor deposition source 16 is provided to vaporize the display panel 12, the vapor deposition source 16 has a vapor deposition side 161 facing the third mask 14c, and the vapor deposition source 16 provides vapor deposition material for forming the green light emitting layer structures 125c. The green light emitting layer structures 125c are formed in the openings 126 corresponding to the through-hole regions 141, and the openings 126 corresponding to the non-perforated regions 142 are blocked.

This forms a vapor deposition of the light emitting layer structure 125 of the entire display panel 12.

The above are only the preferred embodiments of the present disclosure and are not intended to limit the present disclosure. Any modifications, equivalents, and improvements made within the spirit and scope of the present disclosure should be encompassed within the protection scope of the present disclosure.

What is claimed is:

1. A vapor deposition structure of a display panel, comprising:
a display panel;
a plurality of magnets distributed on one side of the display panel;
a mask disposed on another side of the display panel;
a plurality of support columns supported between the mask and the display panel, and each of the support columns corresponding to one of the magnets; and
a vapor deposition source having a vapor deposition side facing the mask.

2. The vapor deposition structure of the display panel according to claim 1, further comprising a bottom plate, wherein the magnets are disposed on one side of the bottom plate, and the display panel is disposed on another side of the bottom plate, wherein the display panel comprises a glass substrate disposed on the bottom plate, a thin film transistor structural layer disposed on the glass substrate, a pixel defining layer disposed on the thin film transistor structure layer and provided with a plurality of openings, and a spacer pillar disposed on the pixel defining layer, wherein the mask is disposed on the spacer pillar, and the support columns are disposed in a same layer as the spacer pillar.

3. The vapor deposition structure of the display panel according to claim 2, wherein the mask has a plurality of through-hole regions and a plurality of non-perforated regions, and each of the through-hole regions corresponds to one of the openings.

4. The vapor deposition structure of the display panel according to claim 3, wherein the through-hole regions are arranged in an array to form a plurality of rows and a plurality of columns of the through-hole regions, the support columns are arranged in an array and positioned in the non-perforated regions to form a plurality of rows and a plurality of columns of the support columns, the rows of the support columns are parallel to the rows of the through-hole regions, and the columns of the support columns are parallel to the columns of the through-hole regions.

5. The vapor deposition structure of the display panel according to claim 4, wherein the support columns and the through-hole regions are staggered in a direction in which the rows of the support columns are positioned or in a direction in which the columns of the support columns are positioned.

6. The vapor deposition structure of the display panel according to claim 4, wherein the magnets are elongated, and each row or each column of the support columns corresponds to one magnet.

7. The vapor deposition structure of the display panel according to claim 3, further comprising a light emitting layer structure disposed in each of the openings, wherein the light emitting layer structure is one of a red light emitting layer structure, a green light emitting layer structure, and a blue light emitting layer structure.

8. The vapor deposition structure of the display panel according to claim 7, wherein each of the through-hole regions corresponds to the red light emitting layer structure, and the non-perforated regions correspond to the green light emitting layer structure and the blue light emitting layer structure, or each of the through-hole regions corresponds to the blue light emitting layer structure, and the non-perforated regions correspond to the green light emitting layer structure and the red light emitting layer structure, or each of the through-hole regions corresponds to the green light emitting layer structure, and the non-perforated regions correspond to the red light emitting layer structure and the blue light emitting layer structure.

9. The vapor deposition structure of the display panel according to claim 8, wherein a shape and size of each of the through-hole regions are matched to a shape and size of a corresponding opening.

10. The vapor deposition structure of the display panel according to claim 1, wherein each of the support columns is a prismatic columnar structure.
